(19) United States
(12) Patent Application Publication
(10) Pub. No.: US 2012/0129355 A1
(43) Pub. Date: May 24, 2012

(54) METHOD FOR TEXTURING A SURFACE OF A SEMICONDUCTOR SUBSTRATE AND DEVICE FOR CARRYING OUT THE METHOD

(75) Inventors: Giso Hahn, Konstanz (DE); Helge Haverkamp, Harrenberg (DE); Jose Nestor Ximello-Quiebras, Konstanz (DE)

(73) Assignee: Universitaet Konstanz, Konstanz (DE)

(21) Appl. No.: 13/322,540

(22) PCT Filed: May 20, 2010
(86) PCT No.: PCT/EP10/56995

§ 371 Date: Jan. 23, 2012

(30) Foreign Application Priority Data
May 25, 2009 (DE) 10 2009 022 477.7

(51) Int. Cl. H01L 21/306

(52) U.S. Cl. 438/745; 156/345.11; 257/E21.219

(57) ABSTRACT

A method for texturing a surface of a semiconductor substrate is proposed. Therein, the surface is etched with an etching solution which etches the semiconductor substrate material, wherein a wetting agent is added to the etching solution, which wetting agent contains water-soluble polymers, in particular in the form of polyvinyl alcohol. Therein, the process temperatures of the etching solution can be increased in comparison to conventional texturing methods, as a result of which the process time can be reduced. Process guidance is simplified and process stability is increased. A suitable texturing device for carrying out the method can, in addition to a basin for accommodating the etching solution and a heater for heating the etching solution to at least 85° C., furthermore have an optionally heatable emptying device for emptying the etching solution out of the basin, a removal device for removing crystallised water-soluble polymers from the etching solution and a circulation device for circulating the etching solution.

### FIELD OF THE INVENTION

The present invention relates to a method for texturing a surface of a semiconductor substrate, in particular of a silicon substrate. The texturing method can be advantageously used in the production of solar cells. The invention furthermore relates to a device for carrying out the method.

### BACKGROUND OF THE INVENTION

Particularly in the production of solar cells, it may be advantageous to selectively texture a surface of a semiconductor substrate such as, for example, of a silicon wafer in order to give the surface an uneven, rough shape and in order in this manner to reduce a reflection of light which strikes the surface. As a result, more photons can penetrate into the substrate of the solar cell and be absorbed there which can contribute to an increase in the efficiency of the solar cell.

At present, 85%-90% of all manufactured solar cells are produced on the basis of crystalline silicon. Around half of these use monocrystalline silicon wafers as the substrate. In order to texture the surface of the substrates of such solar cells, the substrates are generally roughened by wet-chemical means.

A method, commonly used for the industrial production of solar cells, for wet-chemical roughening of silicon substrates uses potassium hydroxide solution or sodium hydroxide solution as an etching means for local etching of the substrate surface. The etching is carried out in this case anisotropically, i.e. various crystal directions within the silicon substrate are etched at different speeds. Due to the fact that the etching process does not begin at the same time over the entire substrate surface, rather first at distributed crystallization nuclei on the substrate surface, a formation of small pyramids distributed across the substrate surface can come about. In the case of a suitable selection of the process parameters, the entire substrate surface can be covered with pyramids with a size of a few micrometers and thus have a microscopic roughness which is advantageous for the absorption properties of the substrate.

It has been shown in this case that a sufficiently pronounced and homogeneous texturing of the substrate surface can generally only be achieved if a wetting agent is additionally added to the etching solution. Isopropanol (IPA, C₃H₈O) is conventionally used as a wetting agent.

It has, however, been observed that, particularly in large-scale industrial use of such conventional texturing methods, significant difficulties can occur in process control and process stability. Moreover, periods of etching until adequate texturing is achieved may be long and overall production times e.g. in the production of solar cells may be significantly extended.

### SUMMARY OF THE INVENTION

There may therefore be a need for a method for texturing a surface of a semiconductor substrate which enables simplified process control and/or improved process stability. There may furthermore be a need for a quick texturing method with short process periods.

The present invention is based among other things on the following finding: Since the speed at which a semiconductor substrate is etched in an etching solution is highly dependent on the temperature of the etching solution, as high as possible a temperature of the etching solution is desired for an industrially deployed texturing procedure. Normally, at the present time, texturing methods with a temperature of the etching solution of more than 80° C. are used. It has, however, been found in this case that as a result of the fact that the isopropanol used as the wetting agent has a boiling point of approximately 82° C., significant quantities of this wetting agent can evaporate during the etching procedure. This can hinder process control and process stability since the concentration of isopropanol in the etching solution should be checked continuously and where required fresh isopropanol should be added. As a result of the continuing supply of fresh isopropanol, on the one hand, e.g. as a result of measurement imprecision and/or metering inaccuracies, fluctuations in the concentration of isopropanol in the etching solution may occur. On the other hand, the supply of fresh isopropanol can also influence the current temperature of the etching solution and thus lead to an undesired influencing of the etching procedure. Moreover, the continuous consumption of isopropanol as a result of evaporation may lead to high consumption costs. The disposal of the used texturing solution can also cause problems since it must potentially be processed at high cost in order to once again separate the chemicals used from one another.

Since the cited problems in process control and process stability occur to a much greater extent the higher the temperature of the etching solution selected during texturing, in industrial use, the temperature of the etching solution may be selected according to experience not significantly higher than 80° C. However, a higher temperature of the etching solution would be desirable for an acceleration of the etching procedure.

According to a first aspect of the present invention, a method for texturing a surface of a semiconductor substrate is proposed which comprises an etching of the surface with an etching solution, the etching solution containing an etching substance which is able to etch the material of the semiconductor substrate. According to the invention, the etching solution additionally contains a wetting agent which contains water-soluble polymers with a degree of polymerisation of more than 1000, in particular in the form of polyvinyl alcohol (PVA, (C₂H₄O)ₙ).

This aspect of the present invention is based in this case on the finding that with water-soluble polymers, in particular water-soluble polymers with a degree of polymerisation of more than 1000, preferably a degree of polymerisation of more than 1500, and more specifically with water-soluble polymers in the form of polyvinyl alcohol, a means has been found which, on the one hand, is suitable as a wetting agent in an etching solution and which, on the other hand, as a result of an adequately high boiling point does not really tend to evaporate out of the etching solution during the etching procedure. As a result of this, process control and process stability can be improved during texturing.

Moreover, as a result of the higher boiling point of a wetting agent formed with water-soluble polymers, the overall temperature of the etching solution during the etching procedure can be selected to be higher, for example, higher than 85° C., preferably higher than 90° C. and more preferably higher than 100° C. Since the boiling point, for example, of polyvinyl alcohol, depending on the degree of polymerisation of the polyvinyl alcohol, may be higher than 200° C., even in the case of such high temperatures, no significant evaporation of the polyvinyl alcohol occurs. An upper limit for the temperature which can be selected for the etching solution during texturing may be determined by the boiling point of the etching solution itself which, depending on the etching solution used, normally lies in the range of 110-130° C.

In order to achieve a good texturing result, an etching solution with at least 0.1 percent by weight polyvinyl alcohol, preferably 0.1 to 0.5 percent by weight polyvinyl alcohol and more preferably 0.15 to 0.2 percent by weight polyvinyl alcohol has proven to be suitable.

In preparing the etching solution, it may be advantageous to continuously circulate the solution during mixing-in of the water-soluble polymer, in particular of the PVA, in order to bring about a faster and more complete dissolving of the polymers. During the etching procedure itself, a further circulation may be helpful in particular to improve the homogeneity of the etching solution. The circulation of the solution can be brought about e.g. by a stirrer, a circulation pump or a so-called gas bubbler for generating gas bubbles within the etching solution.

In particular for etching of a silicon substrate, an etching solution can be used in which potassium hydroxide solution (KOH) and/or sodium hydroxide solution (NaOH) serve as the etching substance. A 1% to 10%, preferably a 4% to 6% potassium hydroxide solution or sodium hydroxide solution in preferably water as a solvent has proved to be advantageous.

It has been observed that the water-soluble polymers, particularly in the case of polyvinyl alcohol, tend to crystallise out when the temperature of the etching solution in which they are dissolved falls below a specific minimum temperature, for example, below 80° C., in particular below 60° C. or to room temperature of around 25° C. This property of the water-soluble polymers or of the polyvinyl alcohol can, on the one hand, as explained in detail further below, be advantageously used. On the other hand, an accumulation of crystallised out polymers or crystallised out polyvinyl alcohol on the semiconductor substrate should generally be reliably prevented since the semiconductor substrate can be exposed to very high temperatures above 700° C. usually in subsequent processing steps and, at such high temperatures, contamination, as caused by accumulated polymers, can lead to a degradation of the semiconductor substrate.

It may therefore be advantageous, after the texturing, to carry out a cleaning step which contains a rinsing of the substrate surface in a rinsing solution. The rinsing solution may simply be water in which the water-soluble polymers can dissolve. Other rinsing solutions in which the water-soluble polymers can dissolve are also conceivable. In particular, it may be advantageous to select the temperature of the rinsing solution used such that a crystallisation out of polymers is prevented or residues which have already been crystallised out are dissolved again. A temperature of the rinsing solution of above 40° C., preferably above 60° C. and more preferably above 80° C. has proved to be advantageous.

It has furthermore been observed that foaming can sometimes occur in the etching solution to which polymer-containing wetting agent is added during texturing etching. This can be effectively suppressed with a so-called defoamer. However, there is the risk in this case that the defoamer can leave organic contaminations on the substrates. In order to minimise the quantity of defoamer used, the substrate surface, before it is etched in the etching solution which contains the polymer-containing wetting agent, can be etched in a different, alternative etching solution in order as a result to at least partially remove a surface damage contained at the surface of the substrate. The alternative etching solution may, in this case, for example, contain a NaOH etching solution, with a concentration of, for example, between 10% and 30%, or a KOH etching solution. The etching step which precedes the actual texture etching for removal of a surface damage can, for example, be adapted such that a surface of the semiconductor substrate is etched several micrometers deep, for example, between 1 and 10 micrometers deep. Such an additional etching process carried out in advance can thus act as a cleaning process in which contamination, which may be contained, for example, in the surface region with a sawing damage, is removed. The semiconductor substrate can subsequently be introduced either directly into the texturing etches containing the polymer-containing wetting agent or alternatively a rinsing step in deionised water can optionally be interposed.

According to a further aspect of the present invention, a device for carrying out the texturing method described above is presented. The device has a basin for accommodating etching solution, a heater for heating the etching solution to at least 85° C., an emptying device for emptying the etching solution out of the basin and a removal device for removal of crystallised water-soluble polymers, in particular, crystallised polyvinyl alcohol, out of the etching solution.

The basin may have a suitable size in order to be able to accommodate a sufficient volume of etching solution therein in order to bring the semiconductor substrates into contact with the etching solution and in particular immerse the semiconductor substrates in the etching solution. The basin should furthermore be produced from a material which can withstand the etching solution for an extended period of time. Plastics, in particular PTFE (polytetrafluoroethylene, Teflon) appear to be suitable.

The heater can, for example, be in direct contact with the etching solution or indirectly heat the walls of the basin. A simply controllable and reliably operable electric heater can be used.

An outlet tube, which is preferably arranged at the lowest point of the basin and by means of which the etching solution can be discharged out of the basin for subsequent disposal, can be easily provided as an emptying device for emptying the etching solution out of the basin. Alternatively, the emptying device can have a pump with the help of which the etching solution can be actively pumped out of the basin.

The emptying device is advantageously fitted with a heater for heating the emptying device to at least above 40° C., preferably to at least 60° C. and more preferably to at least 80° C. Since the water-soluble polymers used as a wetting agent during the texturing method or in particular the polyvinyl alcohol tend, in the event of cooling below a certain threshold temperature, to crystallise out, it should be prevented that the etching solution cools below this temperature during emptying out of the basin. In particular, it should be prevented that, as a result of a cooling below this threshold temperature, crystallised out polymers or crystallised out polyvinyl alcohol accumulate in the emptying device and could ultimately lead to a blocking of the emptying device. With the help of the provided heater the emptying device itself can be kept at a temperature above the critical threshold temperature and thus a crystallisation out of the etching solution within the emptying device can be prevented.

The removal device for removing crystallised water-soluble polymers or in particular crystallised polyvinyl alcohol represents a further differentiating feature in comparison to conventional devices for carrying out a texturing method. The removal device can be formed in a variety of ways.

For example, the removal device can have a filter device for filtering out crystallised water-soluble polymers or in particular crystallised polyvinyl alcohol from an etching solution which flows through the filter device. In this case, the filter device can, for example, be provided as a sieve or as a non-woven fabric. The filter device can be formed such that the etching solution can be freed of crystallised out residues at specific time intervals or continuously during operation of the texturing device. For example, the filtering device can be designed for actively removing etching solution from the basin, filtering it and returning it to the basin. Alternatively, the filtering device can also be integrated in the emptying device, for example, as a sieve within an outlet tube. Crystallised particles can thus be filtered out in a targeted manner during emptying of the basin, as a result of which a random accumulation of such crystallised particles, for example, on parts of the emptying device can be prevented. The filtering device itself can in this case be cleaned or replaced as required.

Alternatively, the removal device can be formed to remove crystallised polymers floating on the etching solution or in particular crystallised polyvinyl alcohol. It has been observed that, if the etching solution cools to below a specific temperature in the basin, a layer of crystallised out polymers or polyvinyl alcohol, which float on the top of the etching solution, is formed. This layer can be removed with the help of a suitably formed removal device such as, for example, a scraper or squeegee which can be moved over the surface of the etching solution or a sieve.

In the event that the etching solution has to be removed out of the basin, for example, since the etching substance is consumed or contaminated by the continuing etching of semiconductor substrates, the etching solution can thus be removed from the basin with the help of the emptying device. In this case, heating of the emptying device can prevent the wetting agent from crystallising out. Alternatively or additionally, a partial crystallisation out of the wetting agent can be accepted or deliberately provoked and the crystallised out wetting agent can be removed out of the etching solution with the help of the removal device.

In order to be able to better mix the etching solution particularly when mixing-in the water-soluble polymers, a circulation device, for example, in the form of a stirrer, a circulation pump or a gas bubbler can be provided in the etching basin. For example, a stirrer can be integrated into the heater or a stirring magnet immersed in the etching solution can be made to rotate by a magnetic field applied from the outside on the etching basin.

The proposed texturing method or the proposed texturing device can be used in particular in the production of solar cells. In particular, it can serve for the texturing of a front side, facing the incoming light, of a solar cell substrate. However, a use for texturing of surfaces in the case of other semiconductor elements is also conceivable.

Although the method according to the invention or the device according to the invention is described here frequently on the basis of the example of the texturing of a semiconductor substrate composed of silicon, other semiconductor substrates, for example, composed of germanium (Ge) or gallium arsenide (GaAs) can also be textured. Both wafers, for example, with a thickness of more than 100 μm, and sufficiently thick thin layers, for example, with a thickness between 1 μm and 100 μm, can be textured.

It should be pointed out that features and embodiments of the invention are described here partially in relation to the texturing method and partially in relation to the texturing device. A person skilled in the art will, however, recognise that the corresponding features can also be transferred in an analogous manner to the texturing device or the texturing method. In particular, the described features can also be combined with one another in any desired manner.

### BRIEF DESCRIPTION OF THE DRAWINGS

The further aspects, features and advantages described above of the present invention are apparent from the following description of specific embodiments with reference to the enclosed drawings, whereby said description and drawings are not to be interpreted as restricting the invention.

FIG. 1 shows a device, as it can be used for carrying out the texturing method, according to one embodiment of the present invention.

FIG. 2 shows a graph in which the reflection of a silicon wafer, which has been textured with the help of a texturing method according to one embodiment of the present invention, is shown in comparison to a conventionally textured silicon wafer.

The drawings are merely schematic and are not true to scale.

### DESCRIPTION OF PREFERRED EMBODIMENTS OF THE INVENTION

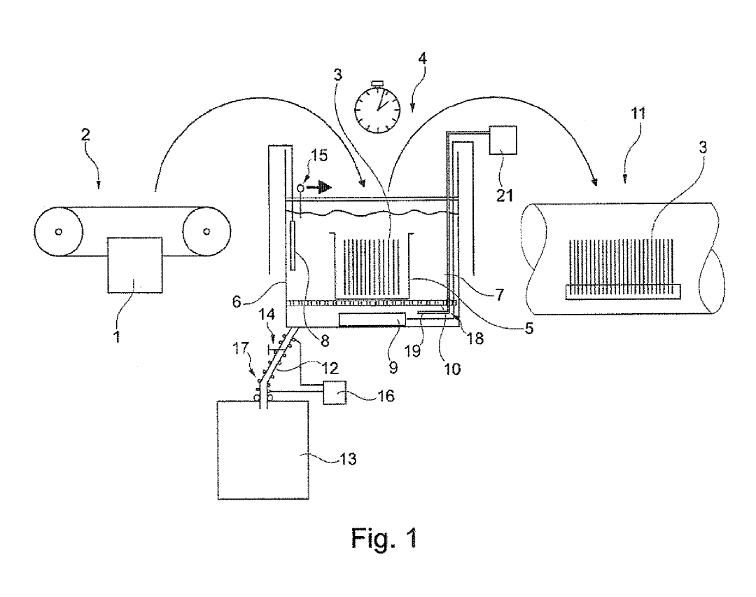

A method and a device for texturing a surface of a semiconductor substrate according to one embodiment of the present invention are explained below with reference to FIG. 1. The texturing method can in this case be used in the context of the production of a solar cell composed of a silicon wafer.

A silicon cuboid 1 referred to as an “ingot” is sawn at a sawing station 2 into thin silicon wafers 3 with the help of fine wires. Silicon wafers 3 are inserted into a texturing device 4 in order to carry out the texturing method. In this case, wafers 3 can be held in a wafer holder 5 and immersed in a basin 6 of texturing device 4. Alternatively, wafers 3 can also be moved across the surface of an etching solution 7 located in basin 6 in such a manner that they are not completely immersed, rather are only made wet by etching solution 7 with one of their surfaces so that only this one surface is textured, whereas the opposite surface is not etched.

In order to reduce or prevent excessive foaming on the etching solution, anti-foaming means, also referred to an antifoam or defoamer, can be mixed with the etching solution. Alternatively, an additional etching step can be carried out prior to the etching step which serves the purpose of the actual texturing with the etching solution which contains the polymer-containing wetting agent. For example, wafer 3 can be etched for 4 minutes in an etching solution composed of NaOH with a concentration of 22% in order to previously remove surface damage down to a depth of approximately 7.5 micrometers and as a result prevent foaming, caused by contamination contained therein, during the subsequent texturing etching.

The temperature of etching solution 7 is measured with a temperature sensor 8 which is in thermal contact with etching solution 7. The temperature of etching solution 7 can in this case be influenced by a heater 9 immersed in etching solution 7. A perforated plate 10 is arranged between heater 9 and wafer holder 5. Once etching solution 7 has been brought to a desired temperature of, for example, 90° C. with the help of heater 9, wafers 3 held in wafer holder 5 can be immersed in etching solution 7 by placing the wafer holder 5 on the perforated plate 10. With the help of a circulation device 18, which is composed, for example, of a tube 19 immersed in etching solution 7 and a gas supply device 21 which blows air or nitrogen into tube 19, the etching solution can be circulated and thus mixed through. After a short etching period of, for example, between 15 and 30 minutes, a texture on the surface of silicon wafer 3 has formed as a result of anisotropic etching with the help of etching solution 7. In this case, the textured wafer surface can have pyramid-like structures, the structure sizes of which can lie in the range of a few μm.

After the etching procedure, wafers 3 can be removed from basin 6 and cleaned by rinsing in pure, deionised water preheated, for example, to 80° C. before they are processed further, for example, by introduction into a diffusion device 11 for diffusion-in of an emitter.

In the case of this embodiment, a solution of 5% potassium hydroxide solution (5% wt. KOH) or 5% sodium hydroxide solution (5% wt. NaOH) in water can be used as etching solution 7. 0.16 percent by weight polyvinyl alcohol is added to the etching solution as a wetting agent.

Polyvinyl alcohol (abbreviation PVA or PVOH) is an artificial thermoplastic plastic. The production of the water-soluble polymer can be carried out by hydrolysis of polyvinyl esters, normally polyvinyl acetate. Similarly to in polyvinyl acetate, the head-to-tail arrangement of the monomers of the vinyl alcohol (sum formula of the monomer: C₂H₄O, molar mass: 44.05 g/mol) predominates in polyvinyl alcohol. The content of building blocks in the head-to-head arrangement is normally below 1-2%. The ratio of these ratios can have a large influence on the physical properties of the polymer such as, for example, on the solubility in water. Polyvinyl alcohol is generally slightly branched as a result of chain transmissions in the synthesis of polyvinyl acetate. The degree of polymerisation is normally approximately 500-2500. The degree of hydrolysation of a technically relevant type varies according to the application between 70 and 100 mol %. If only partially saponified, the acetyl groups can be present distributed statistically or in a block-like manner in the polymer depending on the method. The distribution of the acetyl groups can influence important properties such as the melting point, the surface tension of aqueous solutions or protective colloid properties. Polyvinyl alcohol which has been obtained from polyvinyl acetate can be referred to as atactic plastic. It generally however also has crystalline regions across the hydroxyl groups. The structure and the previous history, i.e. branching, degree of hydrolysation, distribution of the acetyl groups, etc. can have an influence on the crystallinity of the polymer. The higher the degree of hydrolysation, the better the crystallisation capacity. By heat treatment of fully saponified products, the crystallinity can be further increased as a result of which in turn the water solubility is reduced. The higher the ratio of acetyl groups, the weaker the formation of crystalline zones. Polyvinyl alcohol is generally outstandingly layer-forming, emulsifying and adhesive. These properties can be dependent on the humidity since the plastic can absorb water. Water can act as a plasticiser. The melting point can be between 200° C. and 230° C. depending on the degree of hydrolysis and polymerisation. A few well-known commercial names of polyvinyl alcohol include Alcotex®, Elvanol®, Gelvatol®, Gohsenol®, Lemol®, Mowiol®, Rhodoviol® and Polyviol.

Polyvinyl alcohol 72000 was identified as a suitable wetting agent, with 72000 corresponding to the molecular weight. This polyvinyl alcohol can be present in the form of a yellow, largely odourless powder, the pH value of which at 40 g/l in water at 20° C. lies in the range from 3.5 to 7.0.

Texturing device 4 has, at its base, an emptying device 12 in the form of an outlet tube. The outlet tube opens in a disposal container 13. The outlet tube can be heated with the help of a heater 16 composed of heating lines 17 wound around the outlet tube to a temperature of more than 80° C. in order to reliably prevent a crystallisation of polyvinyl alcohol within the outlet tube.

Additionally or alternatively, a filter device 14 in the form of a sieve, which is to be arranged in the outlet tube and is easy to remove therefrom, is provided at the outlet tube. Crystallised polyvinyl alcohol can be easily collected and removed in this manner.

Additionally or alternatively, a further removal device in the form of a scraper 15 can be provided at the upper edge of basin 6 of texturing device 4. Scraper 15 can be guided in the indicated arrow direction along the surface of etching solution 7 accommodated in basin 6. If the temperature of etching solution 7, for example, falls below 50° C., crystallised out polyvinyl alcohol can be deposited on the surface of etching solution 7 in a layer form. This layer can be removed with the help of scraper 15.

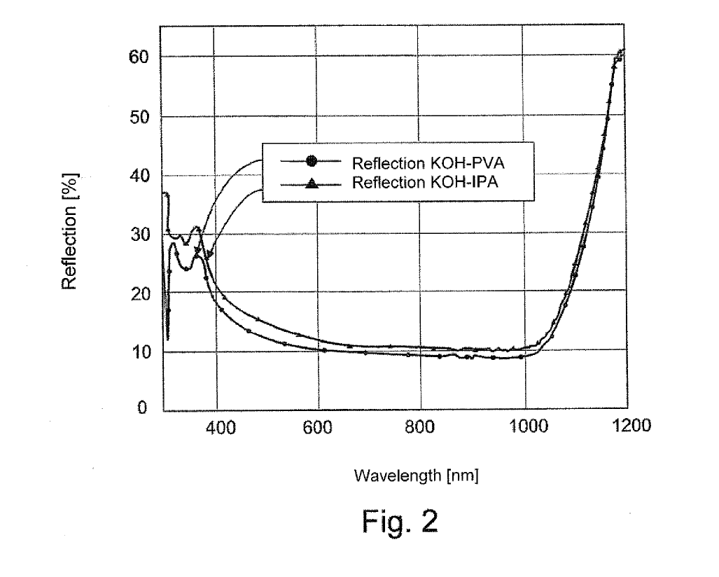

FIG. 2 shows a comparison of the reflection behaviour of differently textured wafers. It becomes clear that the wafers etched with the texturing method proposed here (“KOH-PVA”) have a significantly lower reflection than wafers etched conventionally with isopropanol as the wetting agent (“KOH-IPA”).

Finally, possible technical and commercial advantages of the proposed texturing method can be summarised as follows:

(a) Stabilisation of the etching method: The proposed method enables very high process stability since, in the case of wet-chemical roughening in particular of monocrystalline silicon wafers, the chemicals involved in the process, in particular the wetting agent, no longer noticeably evaporate.

(b) Shortening of process time: As a result of the possibility of increasing the process temperature, it is possible to reduce the required process time in order to thus increase the throughput of the apparatus used.

(c) Simplification of disposal: As a result of the simple separation of the process chemicals, the disposal of used etching solution can be greatly simplified.

Finally, it should be pointed out that the terms “comprise”, “have”, etc. should not rule out the presence of further additional elements. The term “a” or “one” does not exclude the presence of a plurality of elements or subject matters. Moreover, in addition to the method steps cited in the claims, further method steps may be necessary or advantageous in order e.g. to ultimately manufacture a solar cell. The reference numbers in the claims solely serve the purpose of better readability and should not restrict the scope of protection of the claims in any manner.

1. A method for texturing a surface of a semiconductor substrate, comprising:
etching the surface with an etching solution,
wherein the etching solution contains an etching substance which etches the semiconductor substrate material,
wherein the etching solution additionally contains a wetting agent which contains water-soluble polymers with a degree of polymerisation of more than 1000.

2. The method according to claim 1, wherein the wetting agent contains polyvinyl alcohol.

3. The method according to claim 2, wherein the etching solution contains at least 0.1% wt. polyvinyl alcohol.

4. The method according to claim 1, wherein the etching solution is provided during etching with a temperature of more than 85° C.

5. The method according to claim 1, wherein the etching solution contains potassium hydroxide solution or sodium hydroxide solution as the etching substance.

6. The method according to claim 1, wherein the etching solution is continuously circulated prior to etching in order to dissolve the water-soluble polymers and/or during etching.

7. The method according to claim 1, further comprising a cleaning step after the texturing, wherein the cleaning step contains a rinsing of the substrate surface in a hot rinsing solution at more than 60° C.

8. The method according to claim 1, wherein the substrate surface, prior to the etching in the etching solution which contains the wetting agent, is etched in an alternative etching solution in order to at least partially remove a surface damage.

9. A device for carrying out the method according to claim 1, comprising:
a basin for accommodating etching solution;
a heater for heating the etching solution to at least 85° C.;
an emptying device for emptying the etching solution from the basin;
a removal device for removal of crystallised water-soluble polymers from the etching solution.

10. The device according to claim 9, wherein the removal device has a filtering device for filtering out crystallised water-soluble polymers from etching solution which is flowing through.

11. The device according to claim 9, wherein the removal device is formed for removal of crystallised water-soluble polymers floating on the etching solution.

12. The device according to claim 9, wherein the emptying device has a heater for heating the emptying device to at least 60° C.

13. The device according to claim 10, further comprising a circulation device for circulating etching solution within the basin.
